(19) United States
(12) Patent Application Publication
(10) Pub. No.: US 2006/0157222 A1
(43) Pub. Date: Jul. 20, 2006

(54) Heat sink

(75) Inventor: Yen-Hsun Chou, Taoyuan City (TW)

Correspondence Address: BROWDY AND NEIMARK, P.L.L.C.;624 NINTH STREET, NW, SUITE 300, WASHINGTON, DC, 20001-5303, US

(73) Assignee: Yuh-Cheng Chemical LTD., Taipei City (TW)

(21) Appl. No.: 11/037,078

(22) Filed: Jan. 19, 2005

(51) Int. Cl. H05K 7/20

(52) U.S. Cl. 165/80.3; 361/704

(57) ABSTRACT

A heat sink includes a plurality of first fins each having a flat base and two parallel sidewalls perpendicularly extending from two sides of the flat base in same direction and having a first height, and a plurality of second fins each having a flat base arranged in parallel to the flat base of each first fin and two sidewalls perpendicularly extending from two sides of the flat base of the second fin in same direction and having a second height, which is substantially not equal to the first height.

### BACKGROUND OF THE INVENTION

1. Field of the Invention

The present invention relates to a heat sink for dissipating heat from a heat source and more particularly, to a high performance heat sink, which cooperates with the fan to dissipate heat.

2. Description of the Related Art

A regular heat sink is formed of a plurality of fins connected in a stack. The fins are respectively extruded from aluminum or copper, each having a flat base and two sidewalls perpendicularly extending from two sides of the flat base in same direction. The fins have the same specification. By means of the sidewalls, the fins are fastened together and kept in parallel. The pitch between the flat bases of two adjacent fins should be designed subject to magnitude of the wind generated by a fan. The pitch can be relatively reduced to fit a relatively stronger wind generated by a fan. On the contrary, the pitch can be relatively increased to fit a relatively weaker wind generated by a fan.

However, according to aerodynamics, the force of the wind produced by a fan varies with the location. The force of the wind produced by a fan is relatively weaker at the center area and relatively stronger around the border area. Further, according to the fan blade design, the force of the wind produced by a fan varies with the shape of the fan blade. The force of the wind is relatively weaker at the down stream of the central bearing area of the fan blade and relatively stronger at the down stream of the fan blade. Therefore, a heat sink of the aforesaid design that has the same pitch between the flat bases of each two adjacent fins does not achieve a high performance.

### SUMMARY OF THE INVENTION

The present invention has been accomplished under the circumstances in view. It is the primary objective of the present invention to provide a heat sink, which dissipates heat efficiently.

It is another objective of the present invention to provide a heat sink, which can be used in different fields of flow and wind pressures, achieving heat dissipation efficiently.

To achieve these objectives of the present invention, the heat sink comprises a plurality of first fins and a plurality of second fins arranged in a stack. The first fins and the second fins each comprise a flat base and two sidewalls respectively perpendicularly extending from two sides of the flat base in same direction. The two sidewalls of each first fin have a first height. The two sidewalls of each second fin have a second height, which is substantially different from the first height. The first fins and the second fins are stacked together by means of the sidewalls thereof.

### BRIEF DESCRIPTION OF THE DRAWINGS

FIG. 1 is an exploded view of a heat sink according to a preferred embodiment of the present invention.

FIG. 2 is a sectional side view of the heat sink according to the preferred embodiment of the present invention.

### DETAILED DESCRIPTION OF THE INVENTION

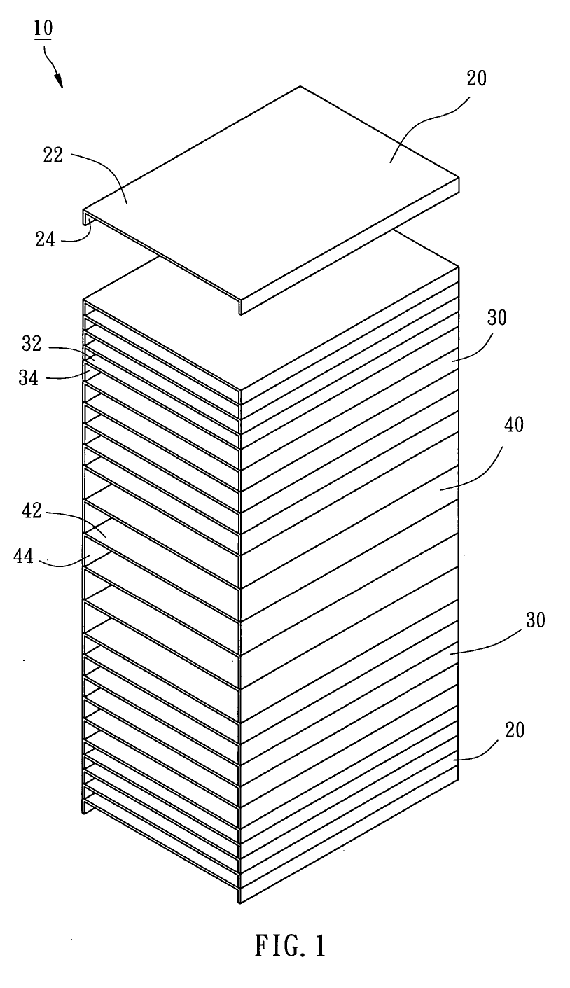

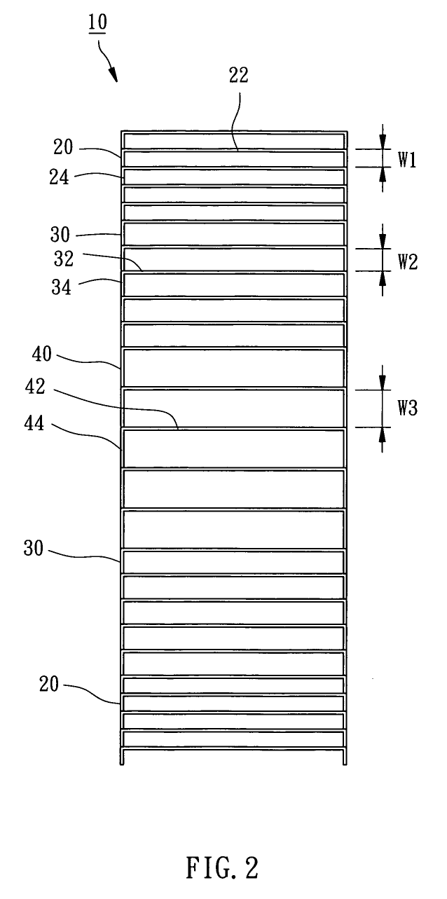

Referring to FIGS. 1 and 2, a heat sink 10 in accordance with a preferred embodiment of the present invention is shown comprised of a plurality of first fins 20, a plurality of second fins 30, and a plurality of third fins 40.

The first fins 20 each have a flat rectangular base 22 and two sidewalls 24 respectively perpendicularly extending from two sides of the flat rectangular base 22 in same direction. The two sidewalls 24 have respectively a first height w1.

The second fins 30 each have a flat rectangular base 32 and two sidewalls 34 respectively perpendicularly extending from two sides of the flat rectangular base 32 in same direction. The two sidewalls 34 have respectively a second height w2, which is greater than the aforesaid first height w1.

The third fins 40 each have a flat rectangular base 42 and two sidewalls 44 respectively perpendicularly extending from two sides of the flat rectangular base 42 in same direction. The two sidewalls 44 have respectively a third height w3, which greater than the aforesaid first height w1 and the aforesaid second height w2.

Further, the sidewalls 24, 34, 44 are preferably formed integral with the respective flat rectangular bases 22, 32, 42.

By means of the sidewalls 24, 34, 44, the fins 20, 30, 40 are fastened together in a stack and arranged in parallel. According to the present preferred embodiment, the third fins 40 are arranged on the middle, the first fins 20 are symmetrically provided at the top and bottom sides, and the second fins 30 are symmetrically arranged at two sides between the first fins 20 and the third fins 40. According to this design, the fins are arranged in a relatively lower density in the center area and relatively higher density at the top and bottom sides. When used with a fan (not shown), the arrangement of the fins 20, 30, 40 fits the relatively weaker force of wind (low air pressure) at the center area of the fan and the relatively stronger force of wind (high air pressure) at the border area of the fan.

In general, the heat sink can be composed of fins of different heights to fit different force of wind and wind pressure from the fan, improving heat dissipation efficiency.

Although a particular embodiment of the invention has been described in detail for purposes of illustration, various modifications and enhancements may be made without departing from the spirit and scope of the invention. For example, the first sidewall and the second sidewall may be respectively perpendicularly extending from two adjacent sides of the body. Accordingly, the invention is not to be limited except as by the appended claims

What is claimed is:

1. A heat sink comprising:
a plurality of first fins each having a flat base and two sidewalls respectively extending from two sides of the flat base, the two sidewalls of each said first fin having a first height;
a plurality of second fins each having a flat base and two sidewalls respectively extending from two sides of the flat base of the second fin, the two sidewalls of each said second fin having a second height, which is substantially not equal to the first height;
wherein the first fins and the second fins are stacked together by means of the sidewalls of the first fins and the second fins such that the flat bases of the first fins and the second fins are arranged in parallel.

2. The heat sink as claimed in claim 1, wherein the two sidewalls of each said first fin extend perpendicularly from the two sides of the flat base of the first fin.
